(19) United States
(12) Patent Application Publication
(10) Pub. No.: US 2025/0305141 A1
(43) Pub. Date: Oct. 2, 2025

(54) MULTI-SECTION SUBSTRATE SUPPORTS AND RELATED METHODS, PROCESS KITS, AND PROCESSING CHAMBERS FOR SEMICONDUCTOR MANUFACTURING

(71) Applicant: Applied Materials, Inc., Santa Clara, CA (US)

(72) Inventors: Vishwas Kumar PANDEY, Madhya Pradesh (IN); Ala MORADIAN, Sunnyvale, CA (US); Anilkumar BODEPUDI, Bangalore (IN)

(21) Appl. No.: 18/618,649

(22) Filed: Mar. 27, 2024

(51) Int. Cl. C23C 16/46; C23C 16/458

(52) U.S. Cl. CPC C23C 16/46; C23C 16/4581

(57) ABSTRACT

Embodiments of the present disclosure relate to multi-section substrate supports, and related process kits, processing chambers, components, and methods for semiconductor manufacturing. In one or more embodiments, a processing chamber includes a substrate support having a plurality of concentric pieces including a first piece having an outer diameter, and a second piece disposed radially outwardly of the first piece. The second piece includes a first outer section that is annular in shape. The processing chamber further includes a plurality of heat sources arranged into a plurality of concentric heating zones. The heating zones include a first heating zone aligned with the first piece, the first heating zone including a first heat source, and a second heating zone aligned with the second piece. The second heating zone includes a second heat source, and the first heat source and the second heat source are independently controllable.

### BACKGROUND

### Field

Embodiments of the present disclosure relate to multi-section substrate supports, and related process kits, processing chambers, components, and methods for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on a surface of the substrate. For example, epitaxy is one deposition process that deposit films of various materials on a surface of a substrate in a processing chamber.

During processing non uniform temperatures can occur for substrates and/or substrate supports. Chamber components can also cause shadowing effects on substrates. The temperature non-uniformities and shadowing effects can cause non-uniform film growth (such as edge roll off) and can hinder the growth rates across the substrate. The adjustability of such parameters can also be limited. Such issues can be exacerbated by relatively complex deposition operations.

Therefore, a need exists for improved apparatus and methods that facilitate one or more of: quick and efficient heating, uniform substrate temperature, and/or improved thermal zonal control and adjustability.

### SUMMARY

Embodiments of the present disclosure relate to multi-section substrate supports, and related process kits, processing chambers, components, and methods for semiconductor manufacturing.

In one or more embodiments, a processing chamber includes a substrate support having a plurality of concentric pieces includes a first piece. The first piece includes an inner section including an opaque material. The inner section has an outer diameter. The substrate support further includes a second piece disposed radially outwardly of the first piece. The second piece includes a first outer section that is annular in shape and includes the opaque material. The first outer section includes a first inner shoulder, and a first inner lip extending inwardly relative to the first inner shoulder. The processing chamber further includes a plurality of heat sources arranged into a plurality of concentric heating zones. The heating zones include a first heating zone aligned with the first piece, the first heating zone including a first heat source, and a second heating zone disposed radially outwardly of the first heating zone and aligned with the second piece. The second heating zone includes a second heat source, wherein the first heat source and the second heat source are independently controllable.

In one or more embodiments, a processing chamber includes a chamber body, a window at least partially defining a processing volume, and a substrate support assembly disposed in the processing volume. The substrate support assembly has a plurality of concentric pieces. The substrate support assembly includes a plurality of support arms, one or more lift pins, a first piece including an inner section including an opaque material, the inner section having an outer diameter; and a second piece disposed radially outwardly of the first piece. The second piece includes a first outer section that is annular in shape and includes the opaque material. a third piece disposed radially outwardly of the second piece. The substrate support assembly further includes the third piece including a second outer section that is annular in shape and includes the opaque material. The processing chamber further includes a plurality of heat sources arranged into a plurality of concentric heating zones. The heating zones include a first heating zone aligned with the first piece. The first heating zone includes a first heat source. The heating zones further include a second heating zone disposed radially outwardly of the first heating zone and aligned with the second piece. The second heating zone includes a second heat source. The heating zones further include a third heating zone disposed radially outwardly of the second heating zone and aligned with the third piece. The third heating zone comprising a third heat source. The first heat source, the second heat source, and the third heat source operate independently from one another.

In one or more embodiments, a method of substrate processing includes positioning a substrate on a substrate support in a process volume. The substrate support has a plurality of concentric pieces that include a first piece including an inner section having an outer diameter, and a second piece including a first outer section that is annular in shape. The method further includes heating the inner section of the substrate support and heating the first outer section of the substrate support relative to the heating of the inner section. The method further includes flowing one or more process gases through the process volume and depositing one or more layers on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross-sectional side view of a processing apparatus, according to one or more embodiments.

FIG. 2 is a schematic cross-sectional side view of the processing apparatus shown in FIG. 1, according to one or more embodiments.

FIG. 3 is a schematic enlarged view of the plate assembly shown in FIGS. 1 and 2, according to one or more embodiments.

FIG. 4 is a schematic partial enlarged axonometric view of the plate assembly shown in FIG. 3, according to one or more embodiments.

FIG. 5 is an enlarged view of one of the one or more first spacers shown in FIGS. 3 and 4, according to one or more embodiments.

FIG. 6 is an enlarged view of one of the one or more first spacers shown in FIGS. 3 and 4, according to one or more embodiments.

FIG. 7A is an enlarged view of one of the one or more first spacers shown in FIGS. 3 and 4, according to one or more embodiments.

FIG. 7B is an enlarged view of one of the one or more first spacers shown in FIGS. 3 and 4, according to one or more embodiments.

FIG. 7C is an enlarged view of one of the one or more first spacers shown in FIGS. 3 and 4, according to one or more embodiments.

FIG. 8 is an enlarged view of one of the one or more first spacers shown in FIGS. 3 and 4, according to one or more embodiments.

FIG. 9 is a schematic axonometric view of a spacer, according to one or more embodiments.

FIG. 10 is a schematic axonometric view of a spacer, according to one or more embodiments.

FIG. 11 is a schematic axonometric view of a plurality of spacers, according to one or more embodiments.

FIG. 12 is a partial schematic axonometric top view of the plate assembly shown in FIGS. 3 and 4, according to one or more embodiments.

FIG. 13 is a partial schematic axonometric bottom view of the plate assembly shown in FIG. 12, according to one or more embodiments.

FIG. 14 is a partial schematic axonometric bottom view of the plate assembly shown in FIG. 12, according to one or more embodiments.

FIG. 15 is a schematic side cross-sectional view of a plate assembly, according to one or more embodiments.

FIG. 16 is a schematic block diagram view of a method of processing substrates for semiconductor manufacturing, according to one or more embodiments.

FIG. 17 is a schematic side cross-sectional view of a plate assembly, according to one or more embodiments.

FIG. 18 is a schematic graphical view of heating profile of a substrate supported by the plate assembly, compared to the heating profile of a substrate supported by another substrate support, according to one or more embodiments.

FIG. 19 is a schematic cross-sectional side view of a processing apparatus, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to multi-section substrate supports, and related process kits, processing chambers, components, and methods for semiconductor manufacturing.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

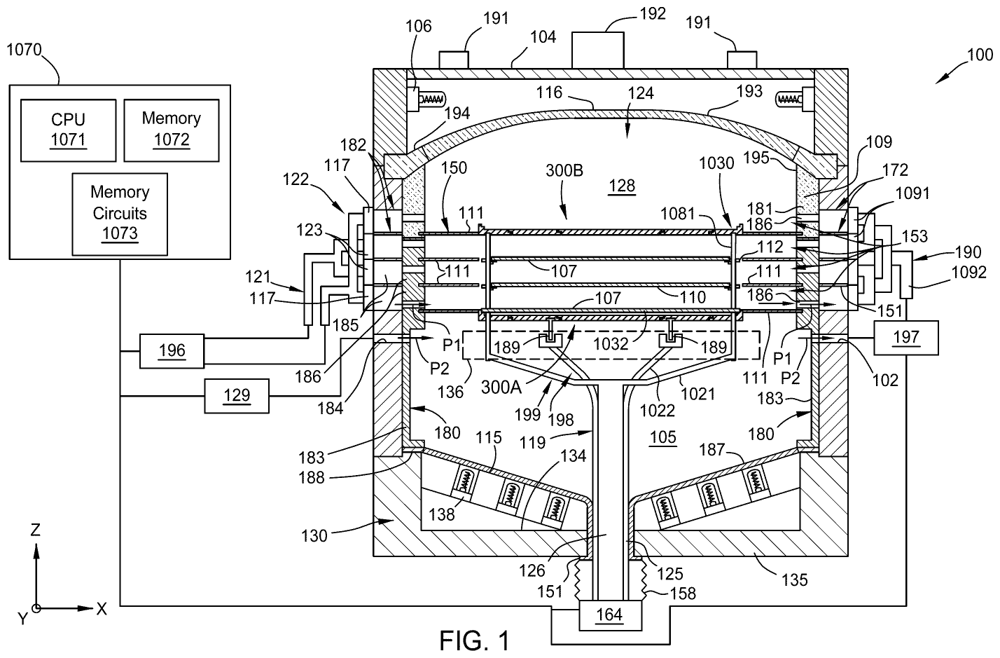

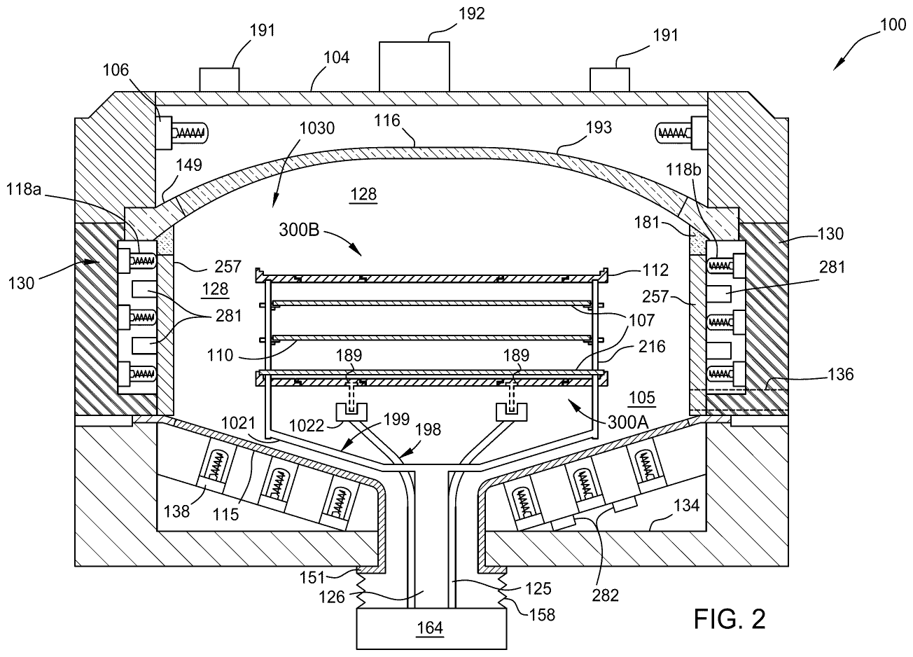

FIG. 1 is a schematic cross-sectional side view of a processing apparatus 100, according to one or more embodiments. The side heat sources 118a, 118b shown in FIG. 2 are not shown in FIG. 1 for visual clarity purposes. The processing apparatus 100 includes a processing chamber having a chamber body 130 that defines an internal volume 124. The processing apparatus 100 includes an upper window 116 and a lower window 115 at least partially defining a processing volume 128 of the internal volume 124.

A cassette 1030 is positioned in the processing volume 128 and at least partially supported by a substrate support assembly 119 (such as a pedestal assembly). The cassette 1030 includes, one or more plate assemblies 300, one or more substrates 107 and one or more heat sinks 110 (e.g., heat sink plate(s)). In one or more embodiments, the cassette 1030 supports two plate assemblies 300A, 300B, two substrates 107 and one heat sink 110 between the two substrates 107. The cassette 1030 can support other numbers of substrates, including but not limited to two substrates 107, three substrates 107, four substrates 107, six substrates 107, or eight substrates 107. In one or more embodiments, the cassette 1030 supports two substrates 107 or three substrates 107. The processing apparatus 100 includes the upper window 116, such as a dome, disposed between a lid 104 and the processing volume 128.

The processing apparatus 100 includes the lower window 115 (such as a lower dome) disposed below the processing volume 128. One or more upper heat sources 106 are positioned above the processing volume 128 and the upper window 116. The one or more upper heat sources 106 can be radiant heat sources such as lamps, for example halogen lamps or ultraviolet (UV) lamps. The one or more upper heat sources 106 are disposed between the upper window 116 and the lid 104. The upper heat sources 106 are positioned to provide uniform heating of the substrates 107. One or more lower heat sources 138 are positioned below the processing volume 128 and the lower window 115. The one or more lower heat sources 138 can be radiant heat sources such as lamps, for example halogen lamps or UV lamps. The lower heat sources 138 are disposed between the lower window 115 and a floor 134 of the internal volume 124. The lower heat sources 138 are positioned to provide uniform heating of the substrates 107.

The present disclosure contemplates that other heat sources may be used (in addition to or in place of the lamps) for the various heat sources described herein. For example, resistive heaters, light emitting diodes (LEDs), and/or lasers may be used for the various heat sources described herein.

The upper and lower windows 116, 115 may be transparent to the infrared radiation, such as by transmitting at least 80% (such as at least 95%) of infrared radiation. The upper and lower windows 116, 115 may include a quartz material (such as a transparent quartz). In one or more embodiments, the upper window 116 includes an inner window 193 and outer window supports 194. The inner window 193 may be a thin quartz window. The outer window supports 194 support the inner window 193 and are at least partially disposed within a support groove. In one or more embodiments, the lower window 115 includes an inner window 187 and outer window supports 188. The inner window 187 may be a thin quartz window. The outer window supports 188 support the inner window 187.

The substrate support assembly 119 is disposed in the processing volume 128. One or more liners 180 are disposed in the processing volume 128 and surround the substrate support assembly 119. The one or more liners 180 facilitate shielding the chamber body 130 from processing chemistry in the processing volume 128. The chamber body 130 is disposed at least partially between the upper window 116 and the lower window 115. The one or more liners 180 are disposed between the processing volume 128 and the chamber body 130. The one or more liners 180 include an upper liner 181 and one or more lower liners 183.

The processing apparatus 100 includes a plurality of gas inject passages 182 formed in the chamber body 130 and in fluid communication with the processing volume 128, and one or more gas exhaust passages 172 (a plurality is shown in FIG. 1) formed in the chamber body 130 opposite the plurality of gas inject passages 182. The one or more gas exhaust passages 172 are in fluid communication with the processing volume 128. Each of the plurality of gas inject passages 182 and one or more gas exhaust passages 172 are formed through one or more sidewalls of the chamber body 130 and through the one or more liners 180 that line the one or more sidewalls of the chamber body 130. As shown, the chamber body 130 can include multiple bodies stacked on each other.

Each gas inject passage 182 includes a gas channel 185 formed in the chamber body 130 and one or more gas openings 186 (one is shown in FIG. 1) formed in the one or more liners 180. One or more supply conduit systems are in fluid communication with the gas inject passages 182. In FIG. 1, an inner supply conduit system 121 and an outer supply conduit system 122 are in fluid communication with the gas inject passages 182. The inner supply conduit system 121 includes a plurality of inner gas boxes 123 mounted to the chamber body 130 and in fluid communication with an inner set of the gas inject passages 182. The outer supply conduit system 122 includes a plurality of outer gas boxes 117 mounted to the chamber body 130 and in fluid communication with an outer set of the gas inject passages 182. The present disclosure contemplates that a variety of gas supply systems (e.g., supply conduit system(s), gas inject passages, and/or gas boxes different than what is shown in FIG. 1) may be used.

The processing apparatus 100 includes a flow guide structure 150 having one or more flow dividers 111 positioned outwardly of the cassette 1030. Four flow dividers 111 are shown in FIG. 1. Other numbers (such as two or three) of the flow dividers 111 may be used. The flow guide structure 150 divides the processing volume into a plurality of flow levels 153 (four flow levels are shown in FIG. 1). In one or more embodiments, the flow guide structure 150 includes at least two (such as at least three) flow levels 153. The plurality of gas inject passages 182 are positioned as a plurality of inject levels such that each gas inject passage 182 corresponds to one of the plurality of inject levels. Each inject level aligns with a respective flow level 153.

The flow guide structure 150, the one or more liners 180 (such as the upper liner 181 and/or the one or more lower liners 183), and/or the cassette 1030 are formed of one or more of quartz (such as transparent quartz, (e.g. clear quartz) and/or opaque quartz (e.g. white quartz, grey quartz, and/or black quartz)), silicon carbide (SiC), and/or graphite coated with SiC.

The one or more flow dividers 111 are coupled to and/or at least partially supported by the one or more liners 180. Portions (e.g., the one or more flow dividers 111) of the flow guide structure 150 may each act as a pre-heat ring for each flow level 153. The one or more flow dividers 111 can be referred to as one or more pre-heat rings.

As described below, the present disclosure contemplates that the flow guide structure 150 can be omitted.

During operations (such as during an epitaxial deposition operation), one or more process gases P1 are supplied to the processing volume 128 through the inner supply conduit system 121 and the outer supply conduit system 122, and through the plurality of gas inject passages 182. The one or more process gases P1 are supplied from one or more gas sources 196 in fluid communication with the plurality of gas inject passages 182. Each of the gas inject passages 182 is configured to direct the one or more processing gases P1 in a generally radially inward direction towards the cassette 1030. As such, in one or more embodiments, the gas inject passages 182 may be part of a cross-flow gas injector. The flow(s) of the one or more process gases P1 can be divided into the plurality of flow levels 153.

The processing apparatus 100 includes an exhaust conduit system 190. The one or more process gases P1 can be exhausted through exhaust gas openings formed in the one or more liners 180, exhaust gas channels formed in the chamber body 130, and then through exhaust gas boxes 1091. The one or more process gases P1 can flow from exhaust gas boxes 1091 and to an optional common exhaust box 1092, and then out through a conduit using one or more pump devices 197 (such as one or more vacuum pumps).

The one or more processing gases P1 can include, for example, purge gases, cleaning gases, and/or deposition gases. The deposition gases can include, for example, one or more reactive gases carried in one or more carrier gases. The one or more reactive gases can include, for example, silicon and/or germanium containing gases (such as silane (SiH₄), disilane (Si₂H₆), dichlorosilane (SiH₂Cl₂), and/or germane (GeH₄)), chlorine containing etching gases (such as hydrogen chloride (HCl)), and/or dopant gases (such as phosphine (PH₃) and/or diborane (B₂H₆)). The one or more purge gases can include, for example, one or more of argon (Ar), helium (He), nitrogen (N₂), hydrogen chloride (HCl), and/or hydrogen (H₂).

Purge gas P2 supplied from a purge gas source 129 is introduced to a bottom region 105 of the internal volume 124 through one or more purge gas inlets 184 formed in the sidewall of the chamber body 130.

The one or more purge gas inlets 184 are disposed at an elevation below the gas inject passages 182. If the one or more liners 180 are used, a section of the one or more liners 180 may be disposed between the gas inject passages 182 and the one or more purge gas inlets 184. The one or more purge gas inlets 184 are configured to direct the purge gas P2 in a generally radially inward direction. The one or more purge gas inlets 184 may be configured to direct the purge gas P2 in an upward direction. During a film formation process, the substrate support assembly 119 is located at a position that can facilitate the purge gas P2 to flow generally along a flow path across a back side of the cassette 1030. The purge gas P2 exits the bottom region 105 and is exhausted out of the processing apparatus 100 through one or more purge gas exhaust passages 102 located on the opposite side of the processing volume 128 relative to the one or more purge gas inlets 184.

The substrate support assembly 119 includes a first support frame 199 and a second support frame 198 disposed at least partially about the first support frame 199. The first support frame 199 includes arms coupled to the cassette 1030 and the plate assemblies 300A, 300B such that lifting and lowering the first support frame 199 lifts and lowers the cassette 1030 and the plate assemblies 300A, 300B. A plurality of lift pins 189 are suspended from the first plate assembly 300A. Lowering of the cassette 1030 and/or lifting of the second support frame 198 initiates contact of the lift pins 189 with arms of the second support frame 198. Continued lowering of the cassette 1030 and/or lifting of the second support frame 198 initiates contact of the lift pins 189 with the substrates in the cassette 1030 such that the lift pins 189 raise the substrates in the cassette 1030. A bottom region 105 of the processing apparatus 100 is defined between the floor 134 and the cassette 1030.

A first shaft 126 of the first support frame 199, a second shaft 125 of the second support frame 198, and a section 151 of the lower window 115 extend through a port formed in a bottom 135 of the chamber body 130 and the floor 134. Each shaft 125, 126 is coupled to one or more respective motors 164, which are configured to independently raise, lower, and/or rotate the cassette 1030 using the first support frame 199, and to independently raise and lower the lift pins 189 using the second support frame 198. The first support frame 199 includes the first shaft 126 and a plurality of first arms 1021 configured to support the cassette 1030 that includes one or more substrate supports 112. The cassette 1030 includes a plurality of mount columns 1081 that support the arcuate substrate supports 112.

The plurality of first arms 1021 include column sections support the cassette 1030 by extending through the first plate assembly 300A, through a plurality of substrate supports 112, and into a second plate assembly 300B. The plate assemblies 300A, 300B as well as the substrate supports 112 are supported by the plurality of first arms. Other configurations are contemplated. For example, column sections of the first arms 1021 can extend partially into the first plate assembly 300A. In one or more embodiments, the first plate assembly 300A supports a substrate 107. The heat sink 110 is supported by one substrate support 112. The heat sink 110 may be made of silicon carbide, graphite coated with silicon carbide, or another opaque material. A second substrate 107 is supported by another substrate support 112. The second plate assembly 300B is positioned at the end of the plurality of first arms 1021. The second plate assembly 300B can define a roof of the cassette 1030 which helps keep the process gases P1 flowing over the substrates 107 at the respective flow levels 153. As shown for the first plate assembly 300A, the plate assemblies described herein are substrate supports. The present disclosure contemplates that, during processing, a substrate 107 can be omitted from one or more of the plate assemblies 300A, 300B (as shown for the second plate assembly 300B in FIGS. 1 and 2).

The second support frame 198 includes the second shaft 125 and a plurality of second arms 1022 configured to interface with and support the lift pins 189. A bellows assembly 158 circumscribes and encloses a portion of the shafts 125, 126 disposed outside the chamber body 130 to facilitate reduced or eliminated vacuum leakage outside the chamber body 130.

An opening 136 (a substrate transfer opening) is formed through the one or more sidewalls of the chamber body 130. The opening 136 may be used to transfer the substrates 107 to or from the cassette 1030, e.g., in and out of the internal volume 124. In one or more embodiments, the opening 136 includes a slit valve. In one or more embodiments, the opening 136 may be connected to any suitable valve that enables the passage of substrates therethrough. The opening 136 is shown in ghost in FIGS. 1 and 2 for visual clarity purposes.

The processing apparatus 100 may include one or more sensors 191, 192, 282, such as temperature sensors (e.g., optical pyrometers) or other metrology sensors, which measure temperatures (or other parameters) within the processing apparatus 100 (such as on the surfaces of the upper window 116, one or more surfaces of the substrates 107, the flow guide structure 150, and/or the cassette 1030). The one or more sensors 191, 192 are disposed on the lid 104. The one or more sensors 282 (e.g., lower pyrometers)—which are shown in FIG. 2—are disposed on a lower side of the lower window 115. The one or more sensors 282 can be disposed adjacent to and/or on the bottom 135 of the chamber body 130.

In one or more embodiments, sensors 191, 192 are oriented toward a top of the cassette 1030, the plate assembly 300, and/or a top of the flow guide structure 150. In one or more embodiments, side sensors 281 (e.g., side temperature sensors) are oriented toward substrate supports 112 of the cassette 1030. In one or more embodiments, lower sensors 282 are oriented toward a bottom of the cassette 1030 (such as a lower surface of the cassette plate 1032), a bottom of the plate assembly 300, and/or a bottom of the flow guide structure 150.

The processing apparatus 100 includes a controller 1070 configured to control the processing apparatus 100 or components thereof. For example, the controller 1070 may control the operation of components of the processing apparatus 100 using a direct control of the components or by controlling controllers associated with the components. In operation, the controller 1070 enables data collection and feedback from the respective chambers to coordinate and control performance of the processing apparatus 100.

The controller 1070 generally includes a central processing unit (CPU) 1071, a memory 1072, and support circuits 1073. The CPU 1071 may be one of any form of a general purpose processor that can be used in an industrial setting. The memory 1072, or non-transitory computer readable medium, is accessible by the CPU 1071 and may be one or more of memory such as random access memory (RAM), read only memory (ROM), floppy disk, hard disk, or any other form of digital storage, local or remote. The support circuits 1073 are coupled to the CPU 1071 and may include cache, clock circuits, input/output subsystems, power supplies, and the like.

The various methods (such as the method 1600) and operations disclosed herein may generally be implemented under the control of the CPU 1071 by the CPU 1071 executing computer instruction code stored in the memory 1072 (or in memory of a particular processing chamber) as, e.g., a software routine. When the computer instruction code is executed by the CPU 1071, the CPU 1071 controls the components of the processing apparatus 100 to conduct operations in accordance with the various methods and operations described herein. In one or more embodiments, the memory 1072 (a non-transitory computer readable medium) includes instructions stored therein that, when executed, cause the methods (such as the method 1600) and operations (such as the operations 1602-1612) described herein to be conducted. The controller 1070 can be in communication with the heat sources, the gas sources, and/or the vacuum pump(s) of the processing apparatus 100, for example, to cause a plurality of operations to be conducted.

FIG. 2 is a schematic cross-sectional side view of the processing apparatus 100 shown in FIG. 1, according to one or more embodiments. The cross-sectional view shown in FIG. 2 is rotated by 55 degrees relative to the cross-sectional view shown in FIG. 1.

The processing apparatus 100 includes one or more side heat sources 118a, 118b (e.g., side lamps, side resistive heaters, side LEDs, and/or side lasers, for example) positioned outwardly of the processing volume 128. One or more second side heat sources 118b are opposite one or more first side heat sources 118a across the processing volume 128.

In FIG. 2, the flow guide structure 150 is not shown for visual clarity purposes. Additionally, the present disclosure contemplates that the flow guide structure 150 can be omitted from the processing apparatus 100 shown in FIGS. 1-2. In such an implementation, the one or more process gases P1 flow into an outer annulus of the processing volume 128 from the gas inject passages 182, and then flow into openings 216 between the plurality of first arms 1021 and outwardly of the substrate supports 112 (e.g., arcuate supports) of the cassette 1030, and then into gaps between the substrates 107. The one or more process gases P1 flow out of the gaps, into the openings 216 (between the plurality of first arms 1021 and outwardly of the substrate supports 112) on an exhaust side of the substrates 107, into the outer annulus of the processing volume 128, and into the one or more gas exhaust passages 172. The present disclosure also contemplates that a plurality of lines (such as conduits) in the processing volume 128 can connect each of the gas inject passages 182 to each of the inlet openings of the cassette 1030.

In addition to the one or more sensors 191, 192 positioned above the processing volume 128, the processing apparatus 100 may include one or more side sensors 281, such as temperature sensors (e.g., optical pyrometers) or other metrology sensors, which measure temperatures (or other parameters) within the processing apparatus 100 (such as on the surfaces of the upper window 116, on the surfaces of the plate assembly 300, and/or one or more surfaces of the substrates 107, the heat sink 110, a plurality of windows 257, and/or the cassette 1030). The plurality of windows 257—if used—can be disposed in gaps between or formed in the one or more liners 180 (such as the upper liner 181 and/or the one or more lower liners 183). The one or more side sensors 281 are side sensors (e.g., side pyrometers) that are positioned outwardly of the processing volume 128, outwardly of the flow guide structure 150, and outwardly of the plurality of windows 257. The one or more side sensors 281 can be radially aligned, for example, with the plurality of windows 257 (as shown in FIG. 2).

The one or more side sensors 281 (such as one or more pyrometers) can be used to measure temperatures within the processing volume 128 from respective sides of the processing volume 128. The side sensors 281 are arranged in a plurality of sensor levels (three sensor levels are shown in FIG. 2). In one or more embodiments, the number of sensor levels is equal to the number of heat source levels. Each side sensor 281 can be oriented horizontally or can be directed (e.g., oriented downwardly at an angle) toward the substrate 107 and the substrate support 112 of a respective level of the cassette 1030.

The present disclosure contemplates that the side heat sources 118a, 118b, the windows 257, and/or the side sensors 281 can be omitted.

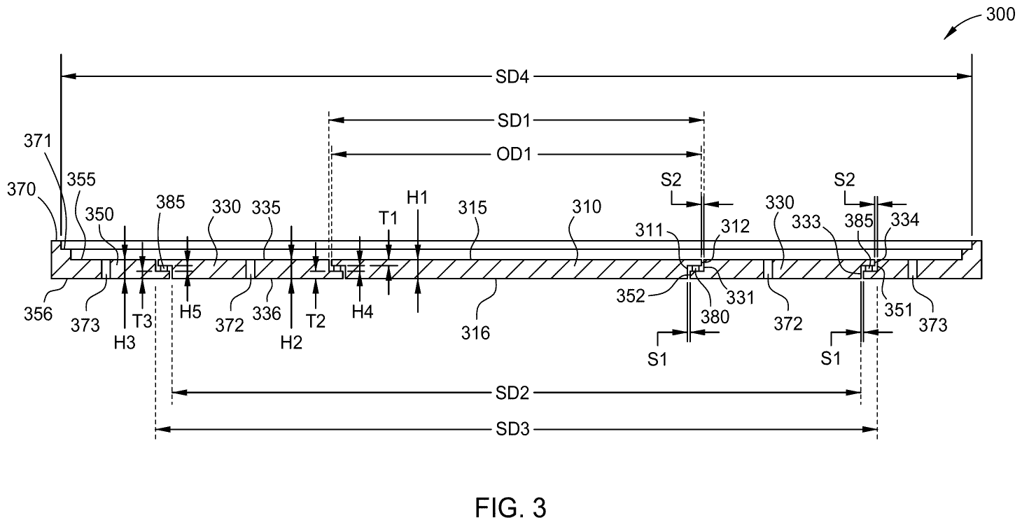

FIG. 3 is a schematic enlarged view of the plate assembly 300 shown in FIGS. 1 and 2, according to one or more embodiments. The plate assembly 300 can be used as one or more of the plate assemblies 300A, 300B shown in FIGS. 1 and 2.

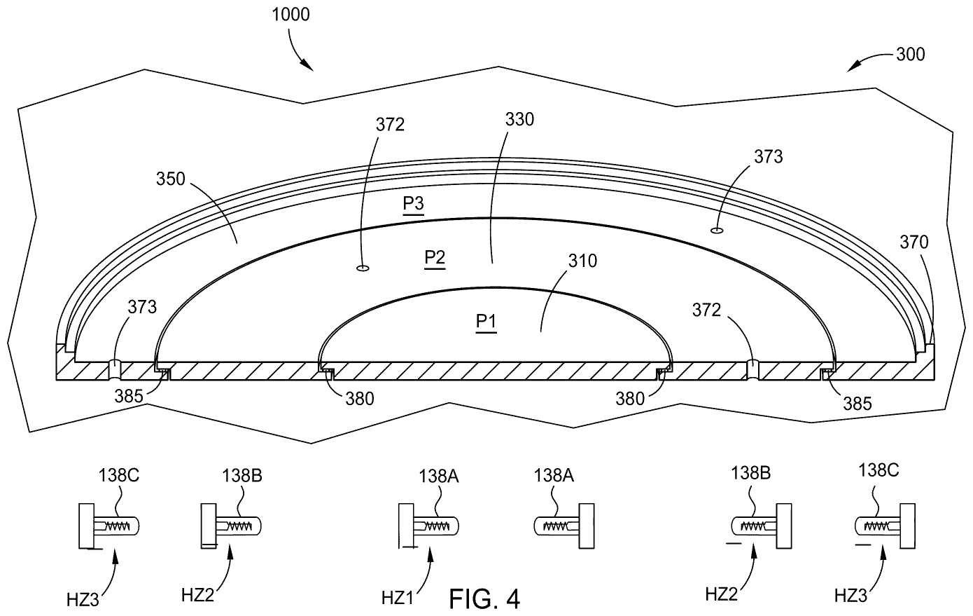

FIG. 4 is a schematic partial enlarged axonometric view of the plate assembly 300 shown in FIG. 3, according to one or more embodiments.

FIGS. 3 and 4 are described together. In one or more embodiments the plate assembly 300 and the plurality of heat sources 138a, 138b, 138c together form a chamber kit 1000 that can be used as part of a processing chamber (such as the processing chamber 100). The plate assembly 300 includes a plurality of concentric pieces including a first piece P1. The first piece P1 includes an inner section 310. In one or more embodiments, the inner section 310 is circular in shape (e.g., disc-shaped). In one or more embodiments, the inner section 310 includes an opaque material. The present disclosure contemplates that the circular shape of the inner section 310 can include a regular circle. The present disclosure also contemplates that the circular shape of the inner section 310 can include one or more openings (such as notches) in an outer edge of the circular shape such that the outer edge is not a continuous circle. As an example, the circular shape of the inner section 310 can include an irregular circle. The inner section 310 has an outer diameter OD1. In one or more embodiments the inner section 310 includes a shoulder 311 and a lip 312 extending outwardly relative to the shoulder 311. The lip 312 has a thickness, and the thickness T1 is a first ratio of a height H1 of the inner section 310. The first ratio is less than 0.4. In one or more embodiments, the first ratio is within a range of 0.25 to 0.38, such as within a range of 0.30 to 0.35, for example about 1:3. In one or more embodiments the thickness T1 of the lip 312 is within a range of 0.7 mm to 1.1 mm (such as about 0.9 mm) and the height H1 of the inner section 310 is within a range of 2.4 mm to 3.0 mm (such as about 2.7 mm).

The plurality of concentric pieces of the plate assembly 300 include a second piece P2 disposed outwardly of the first radial piece P1. The second piece P2 includes a first outer section 330. In one or more embodiments, the first outer section 330 is annular in shape (e.g., ring-shaped). In one or more embodiments, the first outer section 330 includes an opaque material. The first outer section 330 includes a first inner shoulder 331 and a first inner lip 332 extending inwardly relative to the first inner shoulder 331. The first outer section 330 includes a first outer shoulder 333, and a first outer lip 334 extending outwardly relative to the first outer shoulder 333. The first inner shoulder 331 has a first shoulder diameter SD1 that is equal to or greater than the outer diameter OD1 of the inner section 310. The first outer shoulder 333 has a second shoulder diameter SD2 that is greater than the first shoulder diameter SD1. The first inner lip 332 has a second thickness T2, and the second thickness T2 is a second ratio of a second height H2 of the first outer section 330. The second ratio is less than 0.4. In one or more embodiments, the second ratio is within a range of 0.25 to 0.38, such as within a range of 0.30 to 0.35, for example about 1:3. In one or more embodiments the second thickness T2 of the first inner lip 332 is within a range of 0.7 mm to 1.1 mm (such as about 0.9 mm) and the second height H2 of the first outer section 330 is within a range of 2.4 mm to 3.0 mm (such as about 2.7 mm).

In one or more embodiments, the plurality of concentric pieces of the plate assembly 300 include a third piece P3 disposed radially outwardly of the second piece P2. The third piece P3 includes a second outer section 350. In one or more embodiments the second outer section 350 is annular in shape. In one or more embodiments, the second outer section 350 includes an opaque material. The second outer section 350 includes a second inner shoulder 351, and a second inner lip 352 extending inwardly relative to the second inner shoulder 351. The second inner shoulder 351 has a third shoulder diameter SD3 that is equal to or greater than the second shoulder diameter SD2. The second inner lip 352 has a third thickness T3, and the third thickness T3 is a third ratio of a third height H3 of the second outer section 350. The third ratio is less than 0.4. In one or more embodiments, the third ratio is within a range of 0.25 to 0.38, such as within a range of 0.30 to 0.35, for example about 1:3. In one or more embodiments the third thickness T3 of the second inner lip 352 is within a range of 0.7 mm to 1.1 mm (such as about 0.9 mm) and the third height H3 of the second outer section 350 is within a range of 2.4 mm to 3.0 mm (such as about 2.7 mm).

A set of first spacings S1 between the shoulder 311 and the first inner lip 332, and between the first outer shoulder 333 and the second inner lip 352, are greater than the first thickness T1. In one or more embodiments, the first spacings S1 are less than the first height H1. In one or more embodiments, the first spacings S1 are a fourth ratio of the first thickness T1. The fourth ratio is greater than 1.5, such as greater than 2.0. In one or more embodiments, the fourth ratio is within a range of 2.0 to 2.4, such as about 2.22. In one or more embodiments, the first spacings S1 are within a range of 1.3 mm to 2.3 mm, such as about 2.0 mm.

A set of second spacings S2 between the lip 312 and the first inner shoulder 331, and between the first outer lip 334 and the second inner shoulder 351, are greater than the first thickness T1. In one or more embodiments, the second spacings S2 are less than the first height H1. In one or more embodiments, the second spacings S2 are a fifth ratio of the first thickness T1. The fifth ratio is greater than 1.5, such as greater than 2.0. In one or more embodiments, the fifth ratio is within a range of 2.0 to 2.4, such as about 2.22. In one or more embodiments, the second spacings S2 are within a range of 1.3 mm to 2.3 mm, such as about 2.0 mm.

In one or more embodiments the plate assembly 300 includes a ridge 370 that is arcuate in shape (e.g., ring-shaped). In one or more embodiments the ridge 370 and the second outer section 350 are a single monolithic body. The ridge 370 has a lip 371. The lip 371 has a diameter SD4 that is less than or equal to the diameter of a substrate 107 (FIG. 1). During processing a substrate 107 is supported by the lip 371 of the ridge 370 to help keep the substrate 107 stationary during processing. The present disclosure contemplates that the diameter SD4 can be greater than the diameter of the substrate 107 such that the substrate 107 can be disposed within the lip 371 and supported by one or more of the upper exterior surfaces 315, 335, 355 described below. It is contemplated that the ridge 370 can be omitted and the substrate 107 can rest directly on the inner section 310 and one or more outer sections 330, 350. The ridge 370—if included—can add to the third height H3 described above.

In one or more embodiments, the inner section 310 includes a disc body, the first outer section 330 includes a first ring body, and the second outer section 350 includes a second ring body. Each section 310, 330, 350 is a segment of the plate assembly 300. The sections 310, 330, 350 are supported using gravity. The second outer section 350 is at least partially supported using the plurality of first arms 1021 (FIG. 1), the first outer section 330 is at least partially supported using the second outer section 350, and the inner section 310 is at least partially supported using the first outer section 330.

In one or more embodiments a plurality of lift pin holes 372 extend into a lower surface 336 of the first outer section 330. The lift pin holes have a diameter greater than or equal to the diameter of the lift pins 189 (FIG. 1), so that the lift pins 189 can be disposed inside the lift pin holes 372 and raise the substrate 107 for loading and unloading. The present disclosure contemplates that the lift pin holes 372 can be formed in the inner section 310 and/or the second outer section 350. In one or more embodiments, a plurality of arm openings 373 extend into a lower surface 356 of the second outer section 350. The column sections of the first arms 1021 extend into and/or through the arm openings 373. The present disclosure contemplates that the arm openings 373 can be formed in the first outer section 330 and/or the inner section 310.

In one or more embodiments, the inner section 310, the first outer section 330, the second outer section 350, and the ridge 370 each includes an opaque material. Each outer section can be at least partially (such as completely) formed of the opaque material, and/or can be coated with the opaque material. The opaque material can absorb at least 80% (such as 95% or more) of light having a wavelength in the infrared range and/or the ultraviolet range. In one or more embodiments, the opaque material includes one or more of silicon carbide (SiC), graphite coated with SiC, opaque quartz (e.g., white quartz or grey quartz), and/or black quartz.

The plate assembly 300 includes one or more first spacers 380 sized and shaped for disposition between the lip 312 of the inner section 310 and the first inner lip 332 of the first outer section 330. In one or more embodiments, a fourth height H4 of the one or more first spacers 380 can be smaller than a value equal to a height of the shoulder 311 added together with a height of the first inner shoulder 331. In one or more embodiments, a width of the one or more first spacers 380 can be smaller than a width of the lip 312 and smaller than a width of the first inner lip 332. The one or more first spacers 380 can be separately formed from the inner section 310 and the first outer section 330 (as shown in FIG. 3), or the one or more first spacers 380 can be integrally formed with the inner section 310 and/or the first outer section 330 (such that the one or more first spacers 380 are one or more protrusions). The one or more first spacers 380 can abut against the lip 312 and the first inner lip 332 (as shown in FIG. 3), or the one or more first spacers 380 can be recessed into the lip 312 and/or the first inner lip 332.

The fourth height H4 is a sixth ratio of the first height H1 of the inner section 310. The sixth ratio is less than 0.4. In one or more embodiments, the sixth ratio is within a range of 0.25 to 0.38, such as within a range of 0.30 to 0.35, for example about 1:3. In one or more embodiments the fourth height H4 is within a range of 0.7 mm to 1.1 mm (such as about 0.9 mm). In one or more embodiments, the fourth height H4 is about equal to (e.g., within a difference of 5% or less relative to) the first thickness T1.

The plate assembly 300 includes one or more second spacers 385 sized and shaped for disposition between the first outer lip 334 of the first outer section 330 and the second inner lip 352 of the second outer section 350. In one or more embodiments, a fifth height H5 of the one or more second spacers 385 can be smaller than a value equal to a height of the first outer shoulder 333 added together with a height of the second inner shoulder 351. In one or more embodiments, a width of the one or more second spacers 385 can be smaller than a width of the first outer lip 334 and smaller than a width of the second inner lip 352. The one or more second spacers 385 can be separately formed from the first outer section 330 and the second outer section 350 (as shown in FIG. 3), or the one or more second spacers 385 can be integrally formed with the first outer section 330 and/or the second outer section 350 (such that the one or more second spacers 385 are one or more protrusions).

The present disclosure contemplates that one or more of the inner section 310, the first outer section 330, the second outer section 350, the first spacers 380, and/or the second spacers 385 can be coupled to each other.

The fifth height H5 is a seventh ratio of the first height H1 of the inner section 310. The seventh ratio is less than 0.4. In one or more embodiments, the seventh ratio is within a range of 0.25 to 0.38, such as within a range of 0.30 to 0.35, for example about 1:3. In one or more embodiments the fifth height H5 is within a range of 0.7 mm to 1.1 mm (such as about 0.9 mm). In one or more embodiments, the fifth height H5 is about equal to (e.g., within a difference of 5% or less relative to) the third thickness T3. The first and second spacers 380, 385 facilitate providing support with reduced contact areas between the sections 310, 330, 350 of the plate assembly 300, and increased zonal adjustability and control among the sections 310, 330, 350. For example, one of the sections 310, 330, 350 can be heated to a different temperature relative to the other sections 310, 330, 350.

The one or more second spacers 385 can abut against the first outer lip 334 and the second inner lip 352 (as shown in FIG. 3), or the one or more second spacers 385 can be recessed into the first outer lip 334 and/or the second inner lip 352.

The present disclosure contemplates that one or more purge gases P2 can be supplied to the bottom region 105 while flowing the one or more process gases P1. The lips of the plate assembly 300 (such as the lip 312, the first inner lip 332, the first outer lip 334, and the second inner lip 352) facilitate reduced or eliminated leakage of gases past the plate assembly 300 and between the upper section 131 and the processing volume 128. For example, leakage of the one or more purge gases (if used) from the bottom region 105 and into the processing volume 128, and associated dilution of the one or more process gases P1, is reduced or eliminated.

The first and second spacers 380, 385 can include a transparent material (such as transparent quartz) and/or the opaque material. The transparent material transmits at least 80% (such as at least 95%) of light having a wavelength in the infrared range and/or the ultraviolet range. In one or more embodiments, the first and second spacers 380, 385 are formed of a material that is different than the material of the sections 310, 330, 350. In one or more embodiments, the first and second spacers 380, 385 are formed of a transparent material.

In one or more embodiments the first and second spacers 380, 385 are made of an opaque material. In one or more embodiments the first spacers 380 are made of the same material as the first outer section 330. In one or more embodiments the first spacers 380 and the first outer section 330 are a monolithic body and the one or more first spacers 380 protrude relative to the first outer section 330. In one or more embodiments the second spacers 385 are made of the same material as the second outer section 350. In one or more embodiments the second spacers 385 and the second outer section 350 are a monolithic body and the one or more second spacers 385 protrude relative to the second outer section 330.

In one or more embodiments, the first and second spacers 380, 385 are formed of a second material that has a lower thermal conductivity than a first material of the sections 310, 330, 350.

In one or more embodiments, at least part of at least one of the sections 310, 330, 350 includes the transparent material, and sensor(s) (such as the sensors 191 and/or 192) can align with the transparent material to see through the transparent material for measurements. In one or more embodiments, the inner section 310 includes the transparent material or the opaque material, and at least one of the one or more outer sections 330, 350 includes the other of the transparent material or the opaque material. In one or more embodiments, the inner section 310 is formed of the transparent material or the opaque material, and at least one of the one or more outer sections 330, 350 is formed of the other of the transparent material or the opaque material.

The chamber kit 1000 includes the plurality of heat sources 138a, 138b, 138c. The plurality of heat sources 138a, 138b, 138c are arranged in a plurality of concentric heating zones including a first heating zone HZ1. The first heating zone HZ1 is aligned with the first piece P1. In one or more embodiments, the first heating zone HZ1 is directed to heat the first piece P1. The first heating zone HZ1 includes a first heat source 138a. The plurality of heat sources 138a, 138b, 138c includes a second heating zone HZ2. The second heating zone H2 is aligned with the second piece P2. In one or more embodiments, the second heating zone HZ2 is directed to heat the second piece P2. The second heating zone H2 includes a second heat source 138b. The plurality of heat sources 138a, 138b, 138c includes a third heating zone HZ3. The third heating zone HZ3 is aligned with the third piece P3. In one or more embodiments, the third heating zone HZ3 is directed to heat the third piece P3. The third heating zone HZ3 includes a third heat source 138c. The first heat source 138a includes one or more lamps oriented to heat (e.g., by irradiating) the inner section 310 to facilitate heating and adjusting the temperature of first zone(s) of the substrate(s) 107 that align with the inner section 310. The first heat source 138a can be aligned with the inner section 310. The second heat source 138b includes one or more lamps oriented to heat (e.g., by irradiating) the first outer section 330 to facilitate heating and adjusting the temperature of second zone(s) of the substrate(s) 107 that align with the first outer section 330. The second heat source 138b can be aligned with the first outer section 330. The third heat source 138c includes one or more lamps oriented to heat (e.g., by irradiating) the second outer section 350 to facilitate heating and adjusting the temperature of third zone(s) of the substrate(s) 107 that align with the second outer section 350. The third heat source 138c can be aligned with the second outer section 350. In one or more embodiments, the plate assembly 300 can be used to heat the zones of the substrate(s) 107 using at least indirect radiation supplied using the lower heat sources 138. In one or more embodiments, the first heat source 138a, the second heat source 138b, and the third heat source 138c of the lower heat sources 138 are controlled (e.g., using the controller 1070) independently from one another to independently control the temperatures of the first piece P1, the second piece P2, and the piece P3 of the plate assembly 300 (and associated zones of the substrate(s) 107). The inner section 310, the first outer section 330, and/or the second outer section 350 can be heated relative to each other. As an example, the third piece P3 can be heated relative to (e.g., to a higher temperature than) the first piece P1 and/or the second piece P2. The first heat source 138a and/or the first piece P1 can be disposed at a first radial position, the second heat source 138b and/or the second piece P2 can be disposed at a second radial position, and/or the third heat source 138c and/or the third piece P3 can be disposed at a third radial position.

The respective concentric pieces P1, P2, P3 and/or heating zones HZ1, HZ2, HZ3 can be circular or annular in shape. About half of the pieces P1, P2, P3 are shown in FIG. 4.

The gaps and spacings between the inner section 310 and the first outer section 330, as well as the gaps and spacings between the first outer section 330 and the second outer section 350 limit the thermal conductivity between the sections 310, 330, 350 of the plate assembly 300. By adjusting the intensities of the lower heat sources 138, the temperature of each section 310, 330, 350 of the plate assembly 300 can be controlled to a greater precision.

The plate assembly 300 is configured so that an upper exterior surface 315 of the inner section 310, an upper exterior surface 335 of the first outer section 330, and an upper exterior surface 355 of the second outer section 350 are all coplanar to one another. In one or more embodiments, the upper exterior surface 315 is circular in shape. The present disclosure contemplates that the circular shape of the upper exterior surface 315 can include a regular circle. The present disclosure contemplates that the circular shape of the upper exterior surface 315 can include one or more openings (such as notches) in an outer edge of the circular shape such that the outer edge is not a continuous circle. As an example, the circular shape of the upper exterior surface 315 can include an irregular circle.

The plate assembly 300 is configured in a flat arrangement such that upper exterior surfaces of the inner section 310 and outer sections 330, 350 are aligned with each other in a radial direction that points inwardly towards a center of the plate assembly 300. The upper exterior surface 315 of the inner section 310 is aligned with the one or more arcuate upper exterior surfaces 335, 355 of the first and second outer sections 330, 350 respectively.

One or more surfaces of the sections 310, 330, 350 that receive heat (such as the upper exterior surface 315 and/or the one or more outer section upper exterior surfaces 335, 355) are textured (e.g., smoothened) and/or coated to increase an emissivity and/or an absorptivity of the respective sections 310, 330, 350. In one or more embodiments, the one or more exterior surfaces are smoothened by using polishing (e.g., using chemical polishing, mechanical polishing, and/or chemical mechanical polishing). An abrasive material may be used to smoothen the one or more exterior surfaces. Other smoothening techniques may be used. In one or more embodiments, the one or more exterior surfaces are smoothened, and then the coating is formed over the smoothened one or more exterior surfaces. In one or more embodiments, exterior surface(s) of the coating are smoothened. In one or more embodiments, the smoothened one or more exterior surfaces have an average surface roughness (Ra) that is less than 1.5, for example 1.0 or less, such as 0.75 or less. In one or more embodiments, the respective sections 310, 330, 350 have an emissivity and/or an absorptivity for energy in the infrared wavelength range and/or the UV wavelength range that is 0.80 or higher, such as 0.90 or higher, for example 0.95 or higher. In one or more embodiments, one or more of the respective sections 310, 330, 350 are selectively smoothened, and/or coated in one or more regions relative to one or more other regions that are not smoothened and/or coated.

The coating is formed of a material that is different than the material of the respective section 310, 330, 350. In one or more embodiments, the respective section 310, 330, 350 includes graphite, and the coating includes silicon carbide (SiC). In one or more embodiments, the coating includes quartz (such as opaque quartz (e.g., white quartz or grey quartz) and/or black quartz).

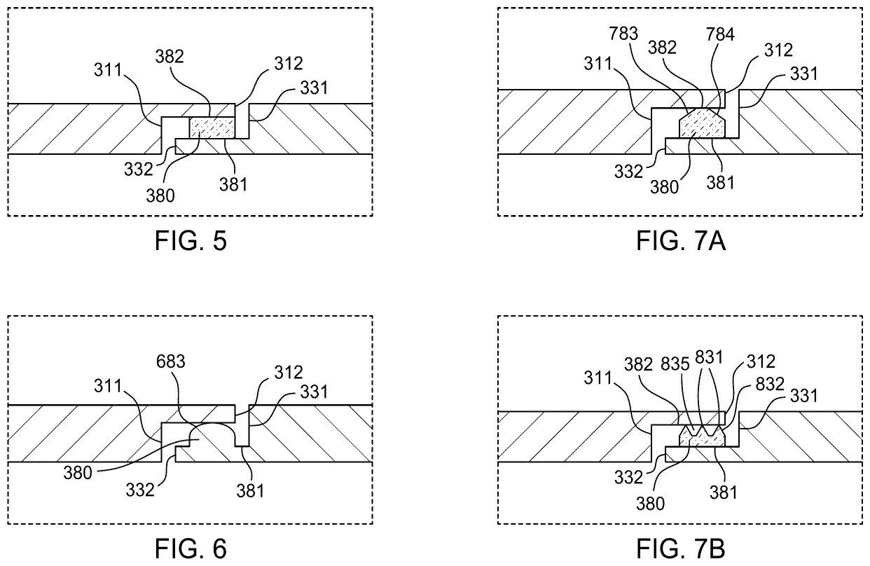

FIG. 5 is an enlarged view of one of the one or more first spacers 380 shown in FIGS. 3 and 4, according to one or more embodiments. In one or more embodiments, the one or more first spacers 380 and/or the one or more second spacers 385 have a rectangular cross-section (as shown in FIG. 5), such as a square cross-section. In one or more embodiments, the one or more first spacers 380 and/or the one or more second spacers 385 include one or more outer surfaces 381, 382 that are planar (e.g., cylindrical, as shown in FIG. 5).

FIG. 6 is an enlarged view of one of the one or more first spacers 380 shown in FIGS. 3 and 4, according to one or more embodiments. In one or more embodiments, the one or more first spacers 380 and/or the one or more second spacers 385 have a semi-ball shaped cross-section (as shown in FIG. 6), such as a semi-spherical or semi-ovular cross-section. In one or more embodiments, the one or more first spacers 380 and/or the one or more second spacers 385 include one or more outer surfaces 381 that are planar and one or more outer surfaces 683 that are tapered or curved (as shown in FIG. 6). As described above, the first spacers 380 can be integrally formed with the first outer section 330 (as shown in FIG. 6) or can be formed as additional bodies relative to the body of the first outer section 330 (as shown in FIGS. 5, 7, and 8).

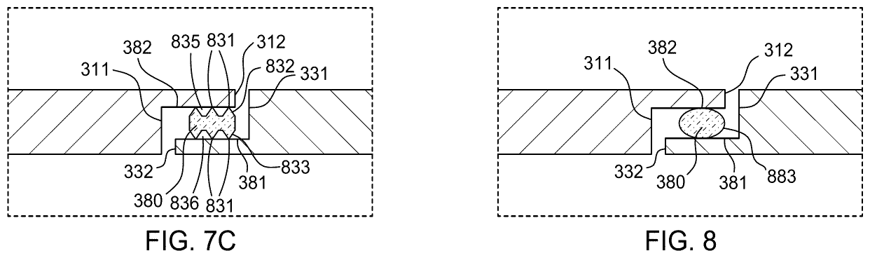

FIG. 7A is an enlarged view of one of the one or more first spacers 380 shown in FIGS. 3 and 4, according to one or more embodiments. In one or more embodiments, the one or more first spacers 380 and/or the one or more second spacers 385 have a semi-trapezoidal shaped cross-section (as shown in FIG. 7A). In one or more embodiments, the one or more first spacers 380 and/or the one or more second spacers 385 include one or more outer surfaces 381, 382 that are planar and one or more outer surfaces 783, 784 that are tapered (as shown in FIG. 7A).

FIG. 7B is an enlarged view of one of the one or more first spacers 380 shown in FIGS. 3 and 4, according to one or more embodiments. In one or more embodiments, the one or more first spacers 380 and/or the one or more second spacers 385 have a saw-tooth shaped cross-section (as shown in FIG. 7B). The one or more first spacers 380 and/or the one or more second spacers 385 include a plurality of tapered outer surfaces 832 and an outer surface 381 that is planar. At least some of the tapered outer surfaces 832 define one or more recesses 835 therebetween (two recesses are shown in FIG. 7B). In one or more embodiments, the one or more first spacers 380 and/or the one or more second spacers 385 include one or more apexes 831.

FIG. 7C is an enlarged view of one of the one or more first spacers 380 shown in FIGS. 3 and 4, according to one or more embodiments. In one or more embodiments, the one or more first spacers 380 and/or the one or more second spacers 385 have a double saw-tooth shaped cross-section (as shown in FIG. 7C). In one or more embodiments, the one or more first spacers 380 and/or the one or more second spacers 385 include a plurality of tapered outer surfaces 832, 833 and one or more apexes 831, 834 on opposite sides of the first or second spacers 380, 385. At least some of the tapered outer surfaces 832, 833 define one or more recesses 835, 836 therebetween (two upper recesses and two lower recesses are shown in FIG. 7C).

FIG. 8 is an enlarged view of one of the one or more first spacers 380 shown in FIGS. 3 and 4, according to one or more embodiments. In one or more embodiments, the one or more first spacers 380 and/or the one or more second spacers 385 have a ball shaped cross-section (as shown in FIG. 8), such as a spherical or ovular cross-section. In one or more embodiments, the one or more first spacers 380 and/or the one or more second spacers 385 include one or more outer surfaces 883 that are arcuate (as shown in FIG. 8).

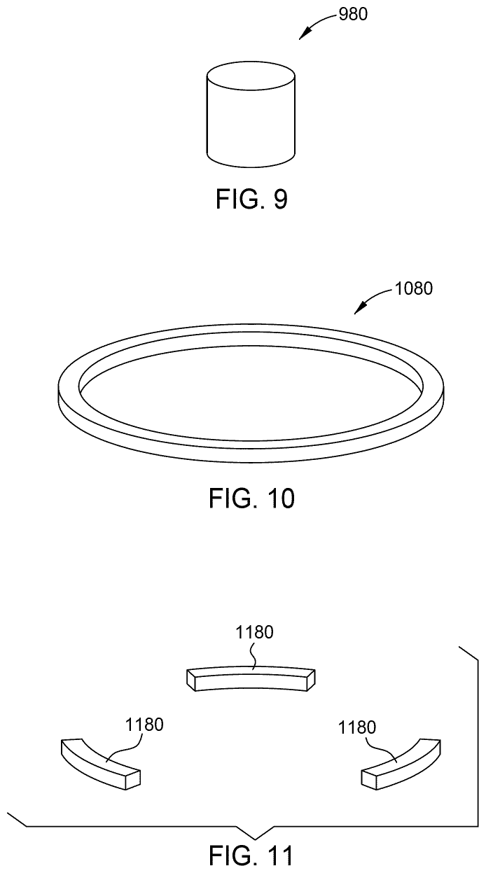

FIG. 9 is a schematic axonometric view of a spacer 980, according to one or more embodiments. The spacer 980 can be used as one or more of the one or more first spacers 380 and/or the one or more second spacers 385. The spacer 980 includes a pin, such as a cylindrical pin.

FIG. 10 is a schematic axonometric view of a spacer 1080, according to one or more embodiments. The spacer 1080 can be used as one or more of the one or more first spacers 380 and/or the one or more second spacers 385. The spacer 1080 includes a ring.

FIG. 11 is a schematic axonometric view of a plurality of spacers 1180, according to one or more embodiments. The spacers 1180 can be used as one or more of the one or more first spacers 380 and/or the one or more second spacers 385. Each of the spacers 1180 includes a ring segment.

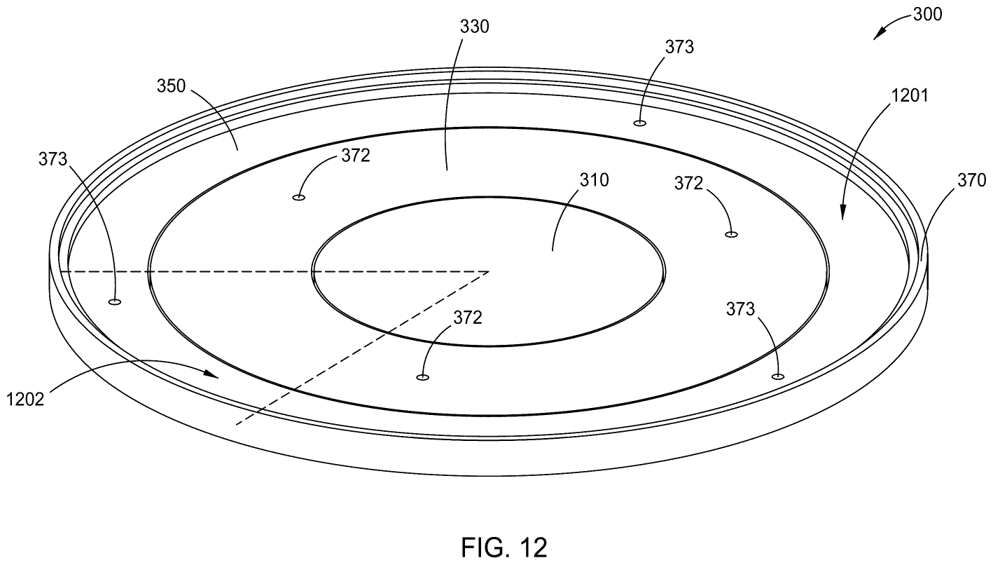

FIG. 12 is a partial schematic axonometric top view of the plate assembly 300 shown in FIGS. 3 and 4, according to one or more embodiments.

In one or more embodiments, each of the inner section 310, the first outer section 330, and the second outer section 350 includes a first portion 1201 formed of the opaque material, and a second portion 1202 formed of the transparent material. The second portion 1202 extends radially outward relative to a center of the respective inner section 310, first outer section 330, or second outer section 350. Sensor(s) (such as the sensors 191 and/or 192) can align with the transparent material of the second portion 1202 to see through the transparent material for measurements.

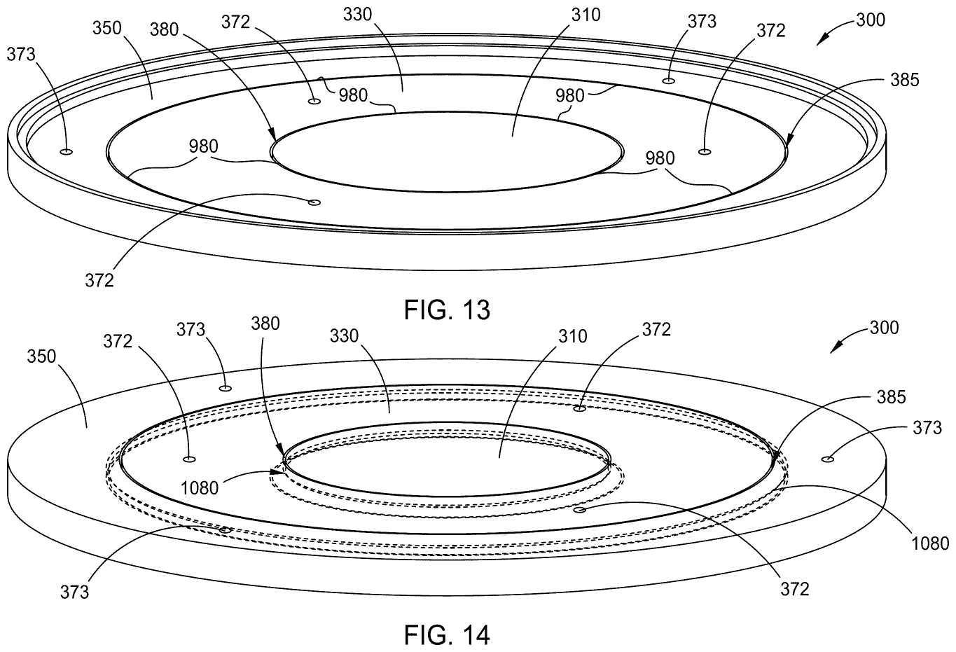

FIG. 13 is a partial schematic axonometric bottom view of the plate assembly 300 shown in FIG. 12, according to one or more embodiments. In FIG. 13, each of the one or more first spacers 380 and the one or more second spacers 385 includes a plurality of pins of the spacer 980 shown in FIG. 9. In one or more embodiments, the one or more first spacers 380 include three or four spacers (four is shown in FIG. 13), and the one or more second spacers 385 include three or four spacers (four is shown in FIG. 13). Other numbers of spacers are contemplated.

FIG. 14 is a partial schematic axonometric bottom view of the plate assembly 300 shown in FIG. 12, according to one or more embodiments. In FIG. 14, each of the one or more first spacers 380 and the one or more second spacers 385 includes the ring of the spacer 1080 shown in FIG. 10.

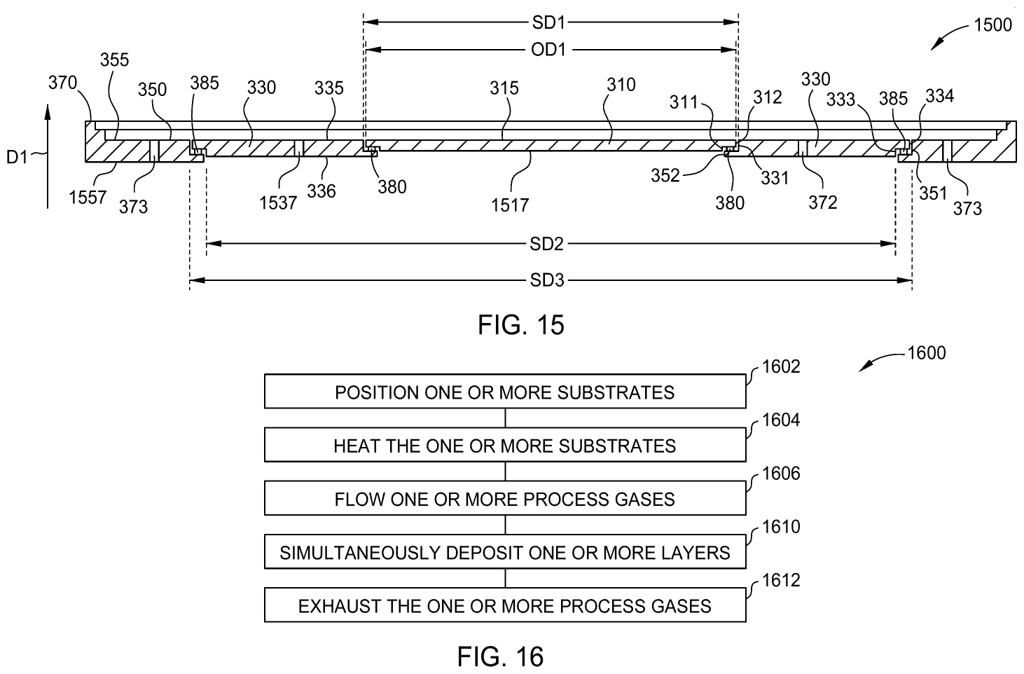

FIG. 15 is a schematic side cross-sectional view of a plate assembly 1500, according to one or more embodiments. The plate assembly 1500 is similar to the plate assembly 300 shown in FIGS. 3 and 4, and includes one or more features, aspects, components, operations, and/or properties thereof. The plate assembly 1500 can be used in place of the plate assembly 300 shown in FIGS. 1 and 2.

An upper face of the plate assembly 1500 is configured in a flat arrangement such that upper exterior surfaces of the inner section 310 and outer sections 330, 350 are aligned with each other in a radial direction that points inwardly towards a center of the plate assembly 1500. The upper exterior surface 315 of the inner section 310 is aligned with the one or more arcuate upper exterior surfaces 335, 355 of the first and second outer sections 330, 350 along the direction D1 from the substrate support assembly 119 and toward the plate assembly 1500. For the plate assembly 1500, height(s) of the one or more first spacers 380, the one or more second spacers 385, the lip 312, the first inner lip 332, the first outer lip 334, and/or the second inner lip 352 can be increased relative to the height(s) shown in FIG. 3. The inner section 310 has a lower external surface 1517 that is offset from one or more arcuate lower external surfaces 1537, 1557 of the outer sections 330, 350. In one or more embodiments the lower external surface 1517 of the inner section 310 is on a different plane along the direction D1 from the lower external surface 1537 of the first outer section 330, which is on a different plane along direction D1 from the lower external surface 1557 of the second outer section 350. In one or more embodiments the lower external surfaces 1517, 1537, 1557 can all be on different planes along the direction D1. In one or more embodiments, the lower external surface 1537 and the lower external surface 1557 can be on the same plane in direction D1. In one or more embodiments, the lower external surface 1517 and the lower external surface 1537 can be on the same plane in direction D1.

Referring back to FIG. 3, both an upper face and a lower face of the plate assembly 300 are configured in a flat arrangement. For example, the upper exterior surfaces 315, 335, 355 are aligned with each other in the radial direction and lower exterior surfaces 316, 336, 356 are aligned with each other in the radial direction.

FIG. 16 is a schematic block diagram view of a method 1600 of processing substrates for semiconductor manufacturing, according to one or more embodiments.

Operation 1602 of the method 1600 includes positioning one or more substrates in a processing volume of a chamber. In one or more embodiments, the substrate is positioned on a substrate support (such as plate assembly 300).

Operation 1604 includes heating the one or more substrates. One or more zones of the one or more substrates can be heated to one or more other zones of the one or more substrates. It is contemplated that operation 1604 may occur prior to, subsequent to, and/or concurrent with operation 1606.

Operation 1606 includes flowing one or more process or inert gases into the processing volume.

Operation 1610 includes simultaneously depositing or baking one or more layers respectively on the one or more substrates. In one or more embodiments, the baking includes hydrogen (H₂) to remove moisture and/or impurities from the substrate.

Operation 1612 includes exhausting the one or more process or inert gases from the processing volume. During the flowing of operation 1606 and/or the exhausting of operation 1612, the one or more process or inert gases can follow the flow paths described herein (such as the flow paths described in relation to FIGS. 1 and 2).

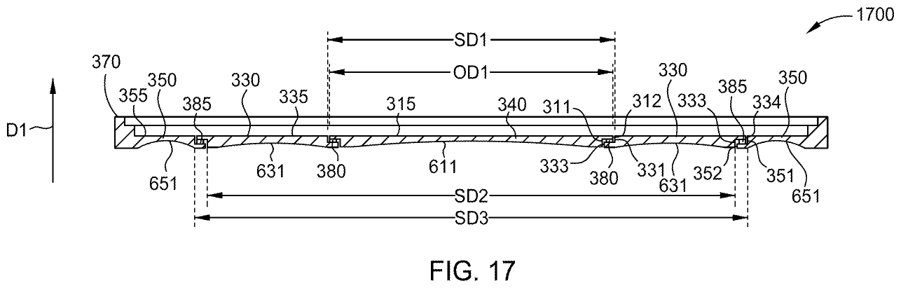

FIG. 17 is a schematic side cross-sectional view of a plate assembly 1700, according to one or more embodiments. The plate assembly 1700 is similar to the plate assembly 300 shown in FIGS. 3 and 4, and includes one or more features, aspects, components, operations, and/or properties thereof. The plate assembly 1700 can be used in place of the plate assembly 300 shown in FIGS. 1 and 2.

The inner section 310 includes one or more arcuate outer surfaces 611. The first and second outer sections 330, 350 respectively include one or more arcuate outer surfaces 631, 651. The arcuate outer surfaces 611, 631, 651 are concave and face the uppermost substrate 107. In one or more embodiments, the arcuate outer surfaces 611, 631, 651 are defined by grooves having arcuate cross-sections formed in the respective inner and outer sections 310, 330, 350. The arcuate outer surfaces of the first and second outer sections 330, 350 are formed circumferentially (e.g., in the shape of a ring) about the one or more arcuate outer surfaces 611 of the inner section 310. In one or more embodiments, the one or more arcuate outer surfaces 611 of the inner section 310 are in the shape of a circle.

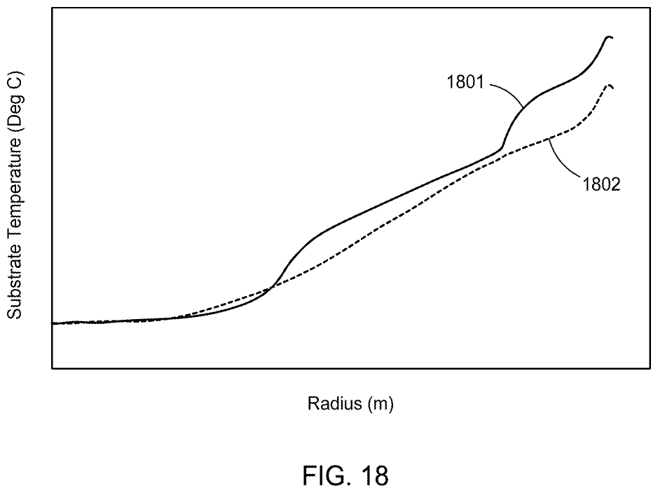

FIG. 18 is a schematic graphical view of a heating profile 1801 of a substrate 107 supported by the plate assembly 300, compared to the heating profile 1802 of a substrate 107 supported by another substrate support, according to one or more embodiments.

The heating profile 1801 of the substrate 107 supported by the plate assembly 300 is believed to exhibit more temperature adjustability, such as at outer zones of substrates. For example, the heating profile 1801 displays a higher substrate temperature at outer zones of substrates (e.g., to reduced or eliminate substrate edge roll-off) when compared to the heating profile 1802 of a substrate 107 supported by another substrate support.

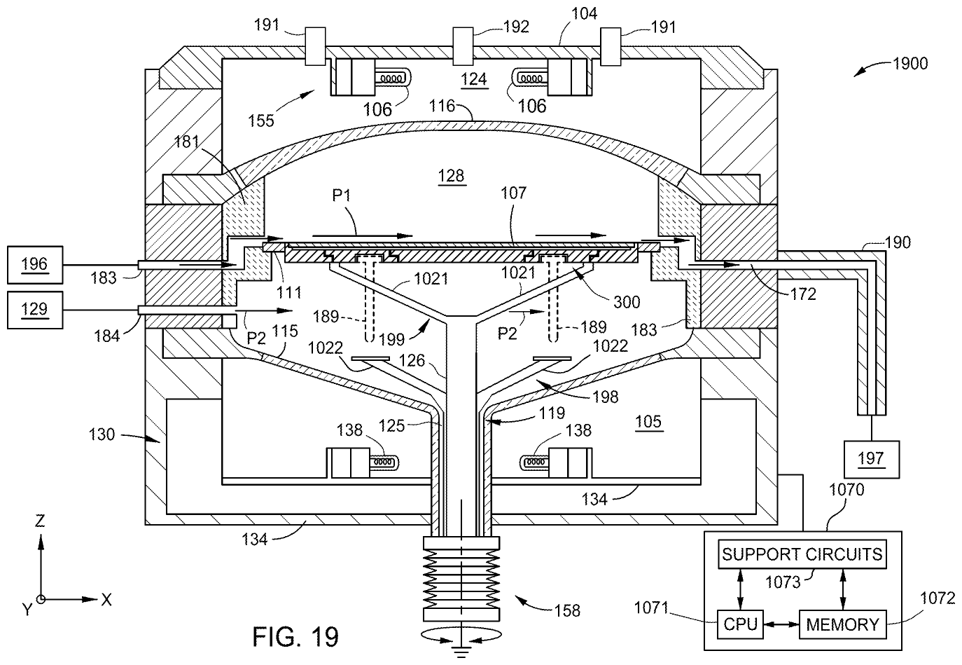

FIG. 19 is a schematic cross-sectional side view of a processing apparatus 1900, according to one or more embodiments. The processing apparatus 1900 is similar to the processing apparatus 100 shown in FIG. 1, and includes one or more of the aspects, features, components, properties, and/or operations thereof. Some components in the processing apparatus 100 may be omitted from the processing apparatus 1900. For example, parts of the cassette 1090 can be omitted, and the processing apparatus 1900 includes one of the flow dividers 111 (e.g., a pre-heat ring) shown in FIG. 1.

In one or more embodiments the processing apparatus 1900 includes the first support frame 199 that supports the plate assembly 300 configured to support a substrate 107. The plate assembly 300 is coupled to and/or rests on the first arms 1021. As shown, the subject matter described herein can be used to process a single substrate 107 at a time in the processing apparatus 1900. During operations (such as during an epitaxial deposition operation), one or more process gases P1 are supplied to the processing volume 128 through the one or more gas inject passages 182 and flow over the substrate 107. The process gas G1 is then exhausted through the exhaust conduit system 190.

Benefits of the present disclosure include increased thermal control and adjustability for a plurality of zones; and quick and efficient heating of the zones (e.g., quickly absorbing and spreading radiation). As an example, the plate assemblies described herein facilitate thermal control and adjustability for a plurality of zones. For example, the plate assemblies described herein facilitate thermal control and adjustability for two or more zones, such as four to eight or more zones. As another example, outer zones of substrates can be heated relative to inner zones to reduce or eliminate edge roll-off. Benefits also include enhanced deposition uniformity, enhanced film thickness, and enhanced device performance.

Such benefits can be facilitated for processing a single substrate at a time, and/or batch processing a plurality of substrates simultaneously.

It is contemplated that one or more aspects disclosed herein may be combined. As an example, one or more aspects, features, components, operations, and/or properties of the various embodiments of the processing apparatus 100, the controller 1070, the liners 180, the plate assembly 300, the spacer implementations shown in FIGS. 5-8, the pin of spacer 980, the ring of spacer 1080, the ring segments of spacers 1180, the plate assembly 300 implementations shown in FIGS. 12 and 13, the plate assembly 300 implementation shown in FIG. 12, the plate assembly 1500, the plate assembly 1700, the method 1600, and/or the processing apparatus 1900 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a substrate support having a plurality of concentric pieces, comprising:
a first piece comprising an inner section comprising an opaque material, the inner section having an outer diameter; and
a second piece disposed radially outwardly of the first piece, the second piece comprising a first outer section that is annular in shape and comprises the opaque material, the first outer section comprising:
a first inner shoulder, and
a first inner lip extending inwardly relative to the first inner shoulder;
a plurality of heat sources arranged into a plurality of concentric heating zones, the heating zones comprising:
a first heating zone aligned with the first piece, the first heating zone comprising a first heat source; and
a second heating zone disposed radially outwardly of the first heating zone and aligned with the second piece, the second heating zone comprising a second heat source, wherein the first heat source and the second heat source are independently controllable.

2. The processing chamber of claim 1, wherein the substrate support further comprises one or more spacers sized and shaped for disposition between the inner section and the first inner lip of the first outer section.

3. The processing chamber of claim 2, wherein the one or more spacers comprise a plurality of pins that comprise a transparent material.

4. The processing chamber of claim 2, wherein the one or more spacers comprise one or more rings that comprise a transparent material.

5. The processing chamber of claim 2, wherein the one or spacers comprise one or more outer surfaces that are tapered or curved.

6. The processing chamber of claim 2, wherein the one or more spacers comprise the opaque material.

7. The processing chamber of claim 2, wherein the one or more spacers and the first outer section are part of a monolithic body, and the one or more spacers protrude relative to the first outer section.

8. The processing chamber of claim 1, wherein the inner section comprises a first exterior surface, the first outer section comprises a second exterior surface, and the inner section is sized and shaped for positioning within the first inner shoulder to align the first exterior surface with the second exterior surface.

9. The processing chamber of claim 1, wherein the first outer section further comprises:
a first outer shoulder; and
a first outer lip extending outwardly relative to the first outer shoulder.

10. The processing chamber of claim 9, wherein the substrate support further comprises a third piece disposed radially outwardly of the second piece, the third piece comprising a second outer section that is annular in shape, the second outer section comprising:
a second inner shoulder; and
a second inner lip extending inwardly relative to the second inner shoulder.

11. The processing chamber of claim 1, wherein the inner section comprises an outer lip having a thickness, wherein the thickness is a ratio of a height of the inner section, wherein the ratio is less than 0.4.

12. The processing chamber of claim 1, wherein the first inner lip of the first outer section has a thickness, wherein the thickness is a ratio of a height of the first outer section, wherein ratio is less than 0.4.

13. A processing chamber comprising:
a chamber body;
a window at least partially defining a processing volume; and
a substrate support assembly disposed in the processing volume, the substrate support assembly having a plurality of concentric pieces, the substrate support assembly comprising:
a plurality of support arms,
one or more lift pins,
a first piece comprising an inner section comprising an opaque material, the inner section having an outer diameter; and
a second piece disposed radially outwardly of the first piece, the second piece comprising a first outer section that is annular in shape and comprises the opaque material;
a third piece disposed radially outwardly of the second piece, the third piece comprising a second outer section that is annular in shape and comprises the opaque material;
a plurality of heat sources arranged into a plurality of concentric heating zones, the heating zones comprising:
a first heating zone aligned with the first piece, the first heating zone comprising a first heat source;
a second heating zone disposed radially outwardly of the first heating zone and aligned with the second piece, the second heating zone comprising a second heat source; and
a third heating zone disposed radially outwardly of the second heating zone and aligned with the third piece, the third heating zone comprising a third heat source, wherein the first heat source, the second heat source, and the third heat source operate independently from one another.

14. The processing chamber of claim 13, wherein the inner section, the first outer section, and the second outer section comprise silicon carbide (SiC).

15. The processing chamber of claim 14, further comprising a controller operable to control the first heat source, the second heat source, and the third heat source independently of each other.

16. The processing chamber of claim 13, further comprising one or more spacers sized and shaped for disposition between the inner section and the first outer section.

17. The processing chamber of claim 13, further comprising one or more spacers sized and shaped for disposition between the first outer section and the second outer section, wherein the first outer section comprises one or more holes having a diameter to receive the one or more lift pins therein.

18. The processing chamber of claim 13, wherein a first exterior surface of the inner section is aligned with a second exterior surface of the first outer section.

19. A method of substrate processing comprising:
positioning a substrate on a substrate support in a process volume, the substrate support having a plurality of concentric pieces comprising:
a first piece comprising an inner section having an outer diameter, and a second piece comprising a first outer section that is annular in shape;
heating the inner section of the substrate support;
heating the first outer section of the substrate support relative to the heating of the inner section;
flowing one or more process gases through the process volume; and
depositing one or more layers on the substrate.

20. The method of claim 19, wherein the substrate is positioned on a first exterior surface of the inner section and a second exterior surface of the first outer section.
